(19) United States
(12) Patent Application Publication
(10) Pub. No.: US 2025/0331291 A1
(43) Pub. Date: Oct. 23, 2025

(54) SEMICONDUCTOR DEVICE

(71) Applicant: Nuvoton Technology Corporation Japan, Kyoto (JP)

(72) Inventors: Atsushi KIMURA, Osaka (JP); Yoshikazu KATO, Osaka (JP); Kazuya OKAMOTO, Osaka (JP)

(21) Appl. No.: 19/252,705

(22) Filed: Jun. 27, 2025

Related U.S. Application Data
(63) Continuation of application No. PCT/JP2024/000962, filed on Jan. 16, 2024.

(30) Foreign Application Priority Data
Jan. 20, 2023 (JP) 2023-007559

(51) Int. Cl. H10D 84/00; H03H 11/12

(52) U.S. Cl. CPC H10D 84/206; H03H 11/1204

(57) ABSTRACT

A semiconductor device includes: a filter circuit including: a resistor; a MOS capacitor; and a MOM capacitor stacked on at least one of the resistor or the MOS capacitor, wherein the following inequalities are satisfied:

Mc≥β−γ/β+γ×Mr

Mr≤\sqrt{1/2πftαβ} [Math. 1]
where ft denotes a cutoff frequency of the filter circuit, Mr denotes a resistor area of a resistor-provided region in which the resistor is provided, Mc denotes a MOS capacitor area of a MOS capacitor-provided region in which the MOS capacitor is provided, α denotes a resistivity of the resistor, β denotes a MOS capacitance rate of the MOS capacitor, and γ denotes a MOM capacitance rate of the MOM capacitor.

### CROSS REFERENCE TO RELATED APPLICATIONS

This is a continuation application of PCT International Patent Application No. PCT/JP2024/000962 filed on Jan. 16, 2024, designating the United States of America, which is based on and claims priority of Japanese Patent Application No. 2023-007559 filed on Jan. 20, 2023. The entire disclosures of the above-identified applications, including the specifications, drawings and claims are incorporated herein by reference in their entirety.

### FIELD

The present disclosure relates to a semiconductor device that includes a filter circuit.

### BACKGROUND

Conventionally, semiconductor devices are known (refer, for example, to Patent Literature (PTL) 1).

### CITATION LIST

### Patent Literature

PTL 1: Japanese Unexamined Patent Application Publication No. 2019-96821

PTL 2: International Publication No. WO2009/044464

PTL 3: Japanese Unexamined Patent Application Publication No. H7-202123

PTL 4: Japanese Unexamined Patent Application Publication No. H11-214960

PTL 5: Japanese Unexamined Patent Application Publication No. H11-168417

### SUMMARY

### Technical Problem

There is a demand for space reduction in the layout area of a semiconductor device that includes a filter circuit.

Accordingly, the present disclosure provides a semiconductor device that includes a filter circuit having favorable layout area efficiency.

### Solution to Problem

A semiconductor device according to one aspect of the present disclosure includes: a filter circuit including: a resistor; a metal oxide semiconductor (MOS) capacitor; and a metal oxide metal (MOM) capacitor stacked on at least one of the resistor or the MOS capacitor, wherein the following inequalities are satisfied:

$$Mc \geq \frac{β - γ}{β + γ} \times Mr \qquad [ Math . 1 ]$$

$$Mr \leq \sqrt{\frac{1}{2 π ft αβ}}$$

where ft denotes a cutoff frequency of the filter circuit, Mr denotes a resistor area that is an area, in a plan view, of a resistor-provided region in which the resistor is provided, Mc denotes a MOS capacitor area that is an area, in the plan view, of a MOS capacitor-provided region in which the MOS capacitor is provided, α denotes a resistivity obtained by dividing a resistance value of the resistor by the resistor area, β denotes a MOS capacitance rate obtained by dividing a capacitance value of the MOS capacitor by the MOS capacitor area, and γ denotes a MOM capacitance rate obtained by dividing a capacitance value of the MOM capacitor by a MOM capacitor area that is an area, in the plan view, of a MOM capacitor-provided region in which the MOM capacitor is provided.

A semiconductor device according to one aspect of the present disclosure includes: a filter circuit including: a first signal input node into which one signal of differential signals is inputted; a second signal input node into which an other signal of the differential signals is inputted; a first signal output node; a second signal output node; a first resistor including one end connected to the first signal input node and an other end connected to the first signal output node; a second resistor including one end connected to the second signal input node and an other end connected to the second signal output node; a first capacitor including one end connected to the first signal output node and an other end connected to ground; a second capacitor including one end connected to the second signal output node and an other end connected to the ground; and a third capacitor including one end connected to the first signal output node and an other end connected to the second signal output node, wherein the first capacitor is realized by one or more MOS transistors each including a gate that is connected to the first signal output node and a source and a drain that are each connected to the ground, the second capacitor is realized by one or more MOS transistors each including a gate that is connected to the second signal output node and a source and a drain that are each connected to the ground, the third capacitor is realized by inter-wiring capacitance between a first wiring and a second wiring, the first wiring being connected to the first signal output node, the second wiring being connected to the second signal output node, and the third capacitor is provided by being stacked on at least one of the first resistor, the second resistor, the first capacitor, or the second capacitor.

### Advantageous Effects

The semiconductor device and the like according to one aspect of the present disclosure provide a semiconductor device that includes a filter circuit having favorable layout area efficiency.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram illustrating the configuration of a semiconductor device and a wireless communication device according to Embodiment 1.

FIG. 2 is a block diagram illustrating the configuration of an envelope detection circuit according to Embodiment 1.

FIG. 3 is a block diagram illustrating the configuration of a DC level extraction low-pass filter according to Embodiment 1.

FIG. 4A is a magnitude plot of a high-pass filter according to Embodiment 1.

FIG. 4B is a magnitude plot of the DC level extraction low-pass filter according to Embodiment 1.

FIG. 4C is a magnitude plot of a filter in which the high-pass filter according to Embodiment 1 has been combined with the DC level extraction low-pass filter according to Embodiment 1.

FIG. 5 is a block diagram illustrating the configuration of a comparator according to Embodiment 1.

FIG. 6 is a block diagram illustrating the configuration of a trimming circuit according to Embodiment 1.

FIG. 7 is a schematic diagram illustrating the layout structure, in plan view, of a typical MOM capacitor.

FIG. 8A is a schematic diagram illustrating the layout structure, in plan view, of a MOM capacitor-provided region according to Embodiment 1.

FIG. 8B is a schematic diagram illustrating the layout structure, in plan view, of a MOS capacitor-provided region according to Embodiment 1.

FIG. 8C is a schematic diagram illustrating the layout structure, in plan view, of a resistor-provided region according to Embodiment 1.

FIG. 9 is a schematic diagram illustrating the layout structure, when viewed obliquely from above, of a structure in which the MOM capacitor according to Embodiment 1 is stacked on the resistor according to Embodiment 1 and the MOS capacitor according to Embodiment 1.

FIG. 10 is a graph illustrating the relationship between resistance value and area in Expression (4) and Expression (5) according to Embodiment 1.

FIG. 11 is a graph illustrating the relationship between resistance value and area in the sum of Expression (4) and Expression (5) according to Embodiment 1.

FIG. 12 is a graph illustrating the relationship between cutoff frequency and total area according to Embodiment 2.

FIG. 13A is a schematic diagram illustrating the layout structure, when viewed obliquely from above, of a DC level extraction low-pass filter according to Embodiment 2 before changing the layout of the wiring layer.

FIG. 13B is a schematic diagram illustrating the layout structure, when viewed obliquely from above, of the DC level extraction low-pass filter according to Embodiment 2 after changing the layout of the wiring layer.

### DESCRIPTION OF EMBODIMENTS

### (Circumstances Leading to Aspects of the Present Disclosure)

So-called contactless IC cards, in which a semiconductor device and an antenna are included within the card, realize various functions such as transmitting and receiving data between a reader/writer device and a semiconductor device and storing data transmitted from a reader/writer device.

In a contactless IC card, when the antenna included in the contactless IC card receives a high-frequency transmission carrier signal transmitted from the reader/writer device, voltage is generated at both ends of the antenna. Then, the semiconductor device included in the contactless IC card rectifies and smooths the voltage to generate the internal voltage necessary for operation of the internal circuitry of the semiconductor device.

In recent years, there has been a demand to increase the communication rate of such contactless IC cards. Typically, so-called amplitude shift keying (ASK), an amplitude shift modulation method represented by ISO 14443 for changing the amplitude of a high-frequency signal, is used for data transmission from a reader/writer device to a contactless IC card.

When the communication rate increases, the ASK modulation cycle shortens, whereby the signal amplitude degrades. Thus, in order to realize an increase in the communication rate, it is necessary to increase the gain of the amplifier circuit.

Conventionally, for example, as disclosed in PTL 4 and PTL 5, there is a known technique involving a demodulator circuit that demodulates data that has been transmitted from a reader/writer device and on which the ASK modulation method has been used. In this technique, the data is demodulated by: a differentiation circuit detecting points of change in the envelope of the received signal; and a comparator that has hysteresis properties determining whether the change direction of the points of change detected is the positive direction or the negative direction. In other words, this technique is a technique in which the points of change in the high-frequency components contained in the data signal are detected.

On the other hand, when the high-frequency components of the data greatly attenuate due to the influence of the inter-power supply load and the like, the amount of change in the points of change in the envelope dramatically decreases. Thus, it becomes difficult to determine whether the change direction of the points of change in the envelope is the positive direction or the negative direction. Accordingly, in order to successfully receive and decode the data transmitted from the reader/writer device to a high rate communication standard while maintaining the communication distance, it is necessary to further increase the gain of the amplifier circuit.

As described above, the demodulator circuit that demodulates the ASK modulated signal has a configuration in which: the points of change in the envelope of the received signal are detected using a differentiation circuit that uses a high-pass filter; the signal of the points of change detected is amplified using an amplifier circuit; and by comparing the amplified signal to the reference voltage (Vref) that is the basis for the amplifier circuit, a comparator having hysteresis properties performs binarization to perform n analog-to-digital conversion on the amplified signal.

When the communication distance increases, the electric field strength of the signal attenuates, whereby the amplitude of the signal of the points of change detected using the differentiation circuit decreases. Thus, in order to secure the communication distance to a further distance, the amplification rate of the amplifier circuit may be increased and the threshold voltage of the hysteresis of the comparator may be decreased.

However, when the amplifier circuit has a high amplification rate, DC offset occurs. In DC offset, the DC level of the output signal of the amplifier circuit deviates from the reference voltage (Vref) due to process variation in the constituent transistor elements, resistor elements, and so forth. Thus, there is a limit to decreasing the threshold voltage of the hysteresis of the comparator. That is to say, due to the difference between the reference voltage (Vref) and the DC level of the output of the amplifier circuit, which occurs due to DC offset occurring in the output signal of the amplifier circuit, the comparator becomes unable to properly compare the signal outputted from the amplifier circuit with the reference voltage (Vref).

To address this, by inputting the output signal of the amplifier circuit into a primary low-pass filter that includes resistor elements and condenser elements, the primary low-pass filter outputs the DC level of the output signal of the amplifier circuit (hereinafter, this DC level may also be referred to as “Vamp”). Then, by inputting Vamp, instead of the reference voltage (Vref), into the comparator, the DC offset is followed by Vamp, even if DC offset occurs in the output signal of the amplifier circuit. This results in the realization of a demodulator circuit that compensates for DC offset that occurs in the output signal of the amplifier circuit and for temperature drift of the DC level.

However, since the cutoff frequency of the primary low-pass filter that outputs Vamp must be set to a low frequency in consideration of the bitrate used for communication, the layout areas of the resistor elements and the condenser elements constituting the primary low-pass filter become larger. In particular, when setting the cutoff frequency of the primary low-pass filter to a low frequency of about several KHz, the constants of the resistance components of the resistor elements and the capacitance components of the condenser elements become larger, whereby the layout areas of the resistor elements and the condenser elements become more significantly larger.

Moreover, when newly designing a primary low-pass filter, it is difficult to identify the reference voltage vacillation amount, the signal amplitude, and the like resulting from variation in temperatures and processes, as well as from simulation error. Thus, it is necessary to perform design in which margins that consider process variation and the like are set. Furthermore, it is necessary to perform preliminary measures such as making element properties adjustable such that the cutoff frequency can be adjusted after prototyping.

Moreover, accompanying expanded integration scales, the diversification of functions, and the like in recent semiconductor devices, the question of how far the layout area of the circuitry installed on semiconductor devices can be limited has become an urgent matter. Demodulator circuits that demodulate ASK modulated signals are also no exception. Thus, there is a demand for the realization of a filter circuit having favorable layout area efficiency.

On the other hand, as a technique for reducing the layout area of a capacitor, for example, PTL 1 discloses a technique in which a metal on semiconductor (MOS) capacitor provided in a diffusion layer, and a metal oxide metal (MOM) capacitor or a metal insulator metal (MIM) capacitor provided in a wiring layer are alternately stacked.

Here, the MOS capacitor refers to a capacitor realized by the gate capacitance of a MOS transistor. Furthermore, the MOM capacitor refers to a capacitor realized by the inter-wiring capacitance of wirings provided in the same wiring layer. Moreover, the MIM capacitor refers to a capacitor realized by the inter-wiring capacitance of wirings provided in different wiring layers.

Furthermore, for example, PTL 2 discloses a technique in which, in the structure of a wiring capacitor in which fringe capacitance is utilized, two wirings that are different from each other and form a capacitor are alternately arranged.

However, while these pieces of patent literature disclose techniques for reducing the layout area of a capacitor, they do not disclose techniques for reducing the layout area of a filter circuit that includes a resistor and a capacitor.

Accordingly, the inventors have diligently repeated experiments and studies regarding a method for improving the layout area efficiency of a filter circuit that includes a resistor and a capacitor. As a result, the inventors have arrived at the below-described semiconductor device according to the present disclosure.

A semiconductor device according to one aspect of the present disclosure includes: a filter circuit including: a resistor; a metal oxide semiconductor (MOS) capacitor; and a metal oxide metal (MOM) capacitor stacked on at least one of the resistor or the MOS capacitor, wherein the following inequalities are satisfied:

$$Mc \geq \frac{β - γ}{β + γ} \times Mr \qquad [ Math . 2 ]$$

$$Mr \leq \sqrt{\frac{1}{2 π ft αβ}}$$

where ft denotes a cutoff frequency of the filter circuit, Mr denotes a resistor area that is an area, in a plan view, of a resistor-provided region in which the resistor is provided, Mc denotes a MOS capacitor area that is an area, in the plan view, of a MOS capacitor-provided region in which the MOS capacitor is provided, α denotes a resistivity obtained by dividing a resistance value of the resistor by the resistor area, β denotes a MOS capacitance rate obtained by dividing a capacitance value of the MOS capacitor by the MOS capacitor area, and γ denotes a MOM capacitance rate obtained by dividing a capacitance value of the MOM capacitor by a MOM capacitor area that is an area, in the plan view, of a MOM capacitor-provided region in which the MOM capacitor is provided.

In the semiconductor device having the above-described configuration, the MOM capacitor included in filter circuit is stacked on the resistor and/or the MOS capacitor included in the filter circuit.

Thus, the above-described semiconductor device provides a semiconductor device that includes a filter circuit having favorable layout area efficiency.

Furthermore, in the semiconductor device, the resistor may be realized by connecting one or more resistors to each other, the one or more resistors each consisting of a different one of one or more polysilicon segments that extend parallel to each other, and in the plan view, an outer circumference of the resistor-provided region may be an outer circumference of a guard ring that includes polysilicon, the guard ring surrounding the one or more polysilicon segments.

This makes it possible to make the resistor included in the filter circuit into a resistor in which influence from outside of the guard ring is inhibited.

Furthermore, in the plan view, the guard ring may further surround one or more dummy polysilicon segments that extend in a direction parallel to a direction in which the one or more polysilicon segments extend.

This makes it possible to make the resistor included in the filter circuit into a resistor in which variation in resistance values is inhibited.

Furthermore, the MOS capacitor may be realized by connecting, to each other, one or more gates that include polysilicon and are each in a different one of one or more MOS transistors, the one or more gates extending parallel to each other, and in the plan view, an outer circumference of the MOS capacitor-provided region may be an outer circumference of a guard ring that includes polysilicon, the guard ring surrounding the one or more MOS transistors.

This makes it possible to make the MOS capacitor included in the filter circuit into a capacitor in which influence from outside of the guard ring is inhibited.

Furthermore, in the plan view, the guard ring may further surround one or more dummy MOS transistors each including a gate that includes polysilicon and extends in a direction parallel to a direction in which the one or more gates extend.

This makes it possible to make the MOS capacitor included in the filter circuit into a capacitor in which variation in capacitance values is inhibited.

Furthermore, the MOM capacitor may be realized by inter-wiring capacitance between a first wiring and a second wiring that are provided in a wiring layer, and in the plan view, an outer circumference of the MOM capacitor-provided region may be an outer circumference of a guard ring consisting of a wiring, the guard ring surrounding the first wiring and the second wiring.

This makes it possible to make the MOM capacitor included in the filter circuit into a capacitor in which influence from outside of the guard ring is inhibited.

A semiconductor device according to one aspect of the present disclosure includes: a filter circuit including: a first signal input node into which one signal of differential signals is inputted; a second signal input node into which an other signal of the differential signals is inputted; a first signal output node; a second signal output node; a first resistor including one end connected to the first signal input node and an other end connected to the first signal output node; a second resistor including one end connected to the second signal input node and an other end connected to the second signal output node; a first capacitor including one end connected to the first signal output node and an other end connected to ground; a second capacitor including one end connected to the second signal output node and an other end connected to the ground; and a third capacitor including one end connected to the first signal output node and an other end connected to the second signal output node, wherein the first capacitor is realized by one or more MOS transistors each including a gate that is connected to the first signal output node and a source and a drain that are each connected to the ground, the second capacitor is realized by one or more MOS transistors each including a gate that is connected to the second signal output node and a source and a drain that are each connected to the ground, the third capacitor is realized by inter-wiring capacitance between a first wiring and a second wiring, the first wiring being connected to the first signal output node, the second wiring being connected to the second signal output node, and the third capacitor is provided by being stacked on at least one of the first resistor, the second resistor, the first capacitor, or the second capacitor.

The semiconductor device having the above-described configuration results in the third capacitor included in the filter circuit being stacked on at least one of the first resistor, the second resistor, the first capacitor, or the second capacitor included in the filter circuit.

Thus, by the above-described semiconductor device, a semiconductor device that includes a filter circuit having favorable layout area efficiency is provided.

Furthermore, the semiconductor device may further include: upstream of the filter circuit, a high-pass filter; and an amplifier circuit; and downstream of the filter circuit, a comparator having hysteresis.

This makes it possible to input, into the filter circuit, a signal that has passed through the high-pass filter and the amplifier circuit, and to input, into the comparator, a signal that has passed through the filter circuit.

Furthermore, the comparator may include a function of adjusting a width of the hysteresis.

This makes it possible to adjust the hysteresis of the comparator.

Furthermore, the semiconductor device may further include: a trimming circuit that adjusts the width of the hysteresis of the comparator.

This makes it possible to adjust the hysteresis of the comparator by using the trimming circuit.

Furthermore, the semiconductor may further include: a clamp circuit that includes a P-channel MOS transistor and that clamps an output of the amplifier circuit.

This makes it possible to clamp the output of the amplifier circuit.

Furthermore, the following inequality may be satisfied:

$$f 3 = \sqrt{f 1 \times f 2} \qquad [ Math . 3 ]$$

where within a range of manufacturing variation in manufacturing the semiconductor device, f1 denotes a minimum cutoff frequency that is a lowest cutoff frequency of the filter circuit and f2 denotes a maximum cutoff frequency that is a highest cutoff frequency of the filter circuit, and when assuming that the manufacturing variation does not occur, f3 denotes a cutoff frequency at a point of intersection between: (1) a waveform of a cutoff frequency of the filter circuit when an area of a first capacitor-provided region is changed while an area of a first resistor-provided region that is most suitable for the filter circuit to realize the minimum cutoff frequency is fixed, the first capacitor-provided region being a region in which the first capacitor and the second capacitor are provided, the first resistor-provided region being a region in which the first resistor and the second resistor are provided; and (2) a waveform of a cutoff frequency of the filter circuit when an area of a second capacitor-provided region is changed while an area of a second resistor-provided region that is most suitable for the filter circuit to realize the maximum cutoff frequency is fixed, the second capacitor-provided region being a region in which the first capacitor and the second capacitor are provided, the second resistor-provided region being a region in which the first resistor and the second resistor are provided.

This makes it possible to, under a condition in which the filter circuit realizes the desired cutoff frequency, relatively easily change the capacitance value of the third capacitor included in the filter circuit.

Hereinafter, specific examples of the semiconductor device according to one aspect of the present disclosure will be described with reference to the Drawings. Each of the embodiments described here indicates a specific example of the present disclosure. Accordingly, the numerical values, shapes, constituent elements, and arrangement and connection of the constituent elements, as well as the steps (processes), the order of the steps, and other details indicated in the following embodiments are merely examples, and are not intended to limit the present disclosure. Moreover, the Drawings are schematic illustrations and are not necessarily precise depictions. In the Drawings, elements that are substantially the same are assigned the same reference signs, and overlapping explanations are omitted or simplified.

### Embodiment 1

Hereinafter, the semiconductor device according to Embodiment 1 will be described with reference to the Drawings.

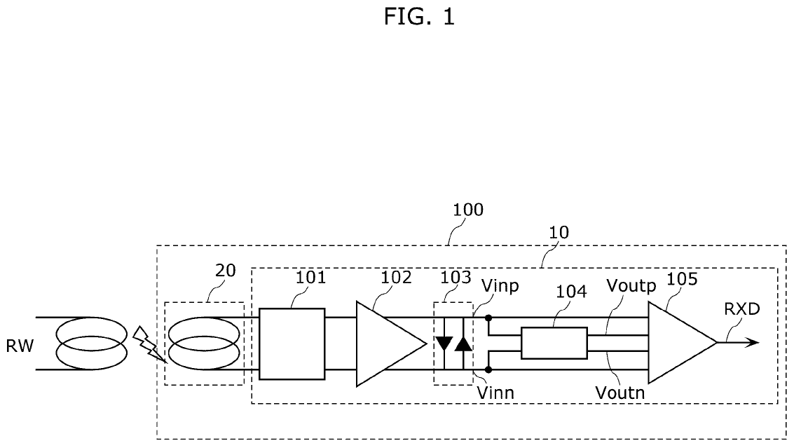

FIG. 1 is a block diagram illustrating the configuration of semiconductor device 10 and wireless communication device 100 that includes semiconductor device 10. Here, wireless communication device 100 is, for example, a contactless IC card.

As illustrated in FIG. 1, wireless communication device 100 includes semiconductor device 10 and antenna 20. Furthermore, semiconductor device 10 includes envelope detection circuit 101, differential amplifier circuit 102, clamp circuit 103, DC level extraction low-pass filter 104, and comparator 105.

Here, differential amplifier circuit 102 is an example of the amplifier circuit. Furthermore, DC level extraction low-pass filter 104 is an example of the filter circuit. Thus, as illustrated in FIG. 1, semiconductor device 10 includes DC level extraction low-pass filter 104, which is an example of the filter circuit.

Antenna 20 receives an ASK modulated signal transmitted from the antenna of a reader/writer device.

Envelope detection circuit 101 extracts a signal subjected to amplitude modulation from the signal received by antenna 20.

Differential amplifier circuit 102 amplifies, by a predetermined amplification rate, the signal subjected to amplitude modulation that has been extracted by envelope detection circuit 101. Differential amplifier circuit 102 outputs, as amplified signals, differential signals consisting of positive signal Vinp and negative signal Vinn, which is the inverted signal of positive signal Vinp.

Clamp circuit 103 clamps the output of differential amplifier circuit 102. Clamp circuit 103 is a circuit that clamps the signal amplitude by a diode connection that uses threshold Vt of a P-channel MOS transistor. Here, an example in which the signal amplitude is clamped to about 350 mV by clamp circuit 103 is described.

DC level extraction low-pass filter 104 receives the input of Vinp and Vinn outputted from differential amplifier circuit 102, extracts the DC level of Vinp by removing the frequency component from Vinp, outputs the extracted DC level as Voutp, extracts the DC level of Vinn by removing the frequency component from Vinn, and outputs the extracted DC level as Voutn.

Comparator 105 has hysteresis. From Vinp, Voutp, Vinn, and Voutn, comparator 105 generates, based on this hysteresis, RXD that is a demodulated digital signal of the AKS modulated signal, and outputs the RXD generated.

The RXD outputted from comparator 105 is subjected to command parsing and/or data acquisition based on a communication standard protocol, by the downstream logic circuit, not illustrated, and/or the downstream microcontroller, not illustrated. The command parsing and data acquisition based on the communication standard protocol is well-known through, e.g., standards specifications such as ISO 14443; thus, explanation thereof is omitted here.

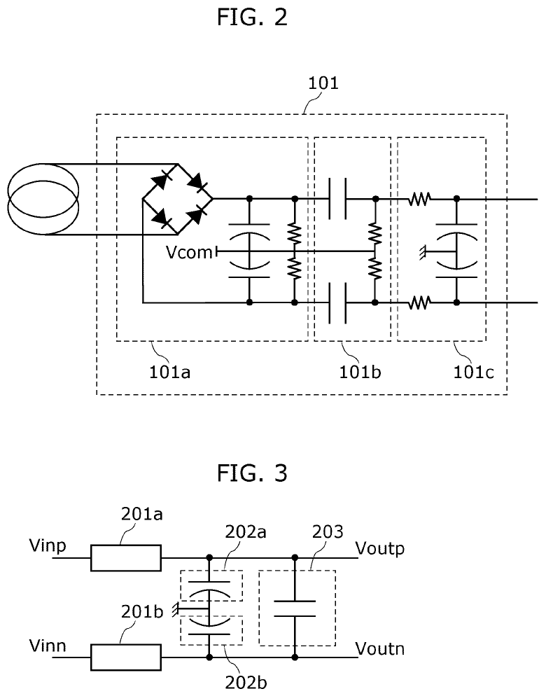

FIG. 2 is a block diagram illustrating the configuration of envelope detection circuit 101.

As illustrated in FIG. 2, envelope detection circuit 101 includes envelope detector 101a, high-pass filter 101b, and carrier removal low-pass filter 101c.

Envelope detector 101a has a diode bridge and a filter circuit. Using the diode bridge and the filter circuit, envelope detector 101a extracts, from a modulated signal included in a communication carrier signal that has a carrier frequency of, e.g., 13.56 MHz and has been received using antenna 20, an envelope signal that indicates the envelope, and outputs the envelope signal extracted.

High-pass filter 101b differentiates the envelope signal extracted using envelope detector 101a to detect points of change in the envelope, and outputs the differentiated envelope signal.

Carrier removal low-pass filter 101c removes signal components of the carrier frequency from the differentiated envelope signal outputted from high-pass filter 101b, and outputs the differentiated envelope signal that has no carrier noise.

Here, carrier removal low-pass filter 101c is, for example, a low-pass filter that removes high-frequency signals of, e.g., 13.56 MHz. Thus, the impact on the areas of the resistor elements and condenser elements that constitute carrier removal low-pass filter 101c is not large.

FIG. 3 is a block diagram illustrating the configuration of DC level extraction low-pass filter 104.

As illustrated in FIG. 3, DC level extraction low-pass filter 104 is a primary low-pass filter that includes first resistor 201a, second resistor 201b, first capacitor 202a, second capacitor 202b, and third capacitor 203.

First resistor 201a is a resistor that has one end connected to Vinp and the other end connected to Voutp.

Second resistor 201b is a resistor that has one end connected to Vinn and the other end connected to Voutn.

First capacitor 202a is a capacitor that has one end connected to Voutp and the other end connected to ground.

Here, first capacitor 202a is described as being realized by one or more MOS transistors having a gate connected to Voutp and a source and drain connected to ground.

Second capacitor 202b is a capacitor that has one end connected to Voutn and the other end connected to ground.

Here, second capacitor 202b is described as being realized by one or more MOS transistors having a gate connected to Voutn and a source and drain connected to ground.

Third capacitor 203 is a capacitor that has one end connected to Voutp and the other end connected to Voutn.

Here, third capacitor 203 is described as being realized by the inter-wiring capacitance between wiring connected to Voutp and wiring connected to Voutn.

Furthermore, third capacitor 203 is provided by being stacked on first resistor 201a, second resistor 201b, first capacitor 202a, and/or second capacitor 202b. Due to this layout structure, DC level extraction low-pass filter 104 is a filter circuit having favorable layout area efficiency.

DC level extraction low-pass filter 104 removes a signal component from the inputted Vinp and Vinn (that is to say, the frequency component), and outputs Voutp and Voutn that are the DC level of these.

It is necessary for DC level extraction low-pass filter 104 to remove, to the greatest extent possible, the signal component from Vinp and Vinn and output a DC level having the smallest ripples possible; thus, it is necessary for the cutoff frequency to be less than or equal to the minimum rate frequency of the signal component.

For example, in the case of the B-type communication standard of ISO 14443, the minimum data rate is about 106 Kbit/s. In this case, when eight bits of data are a pattern in which 0 and 1 repeat, the rate frequency of the signal component is about 53 KHz, and when eight bits of data are a pattern in which only 0 or 1 repeats, the rate frequency of the signal component is about 5.3 KHz. Thus, it is necessary for the cutoff frequency of DC level extraction low-pass filter 104 in this case to be less than or equal to 5.3 KHz.

Hereinafter, the frequency properties of Voutp and Voutn outputted from DC level extraction low-pass filter 104 will be described with reference to the Drawings.

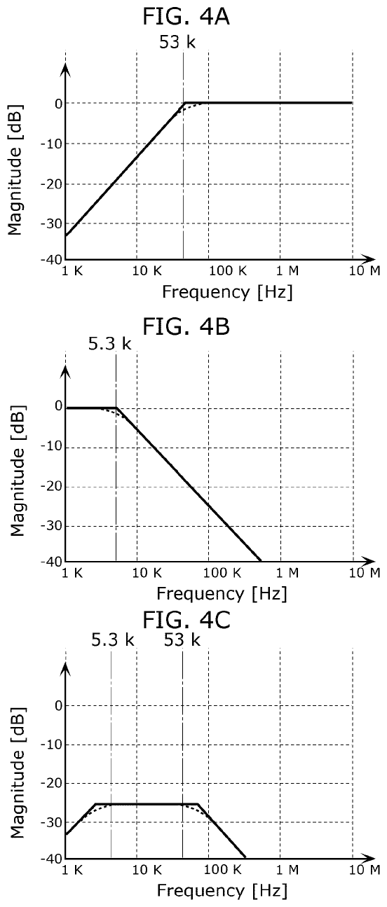

FIG. 4A is a magnitude plot of high-pass filter 101b when the cutoff frequency of high-pass filter 101b is set to 53 KHZ, corresponding to the maximum repeating frequency at 106 KHz.

FIG. 4B is a magnitude plot of DC level extraction low-pass filter 104 when the cutoff frequency of DC level extraction low-pass filter 104 is set to 5.3 KHz.

FIG. 4C is a magnitude plot of a filter in which high-pass filter 101b has been combined with DC level extraction low-pass filter 104.

As illustrated in FIG. 4C, the frequency properties of the output of DC level extraction low-pass filter 104 are properties in which attenuation of about 25 db is caused with respect to the signal in the range of 5.3 KHZ to 53 KHZ, being the signal band of the communication carrier signal. In other words, it is revealed that the output of DC level extraction low-pass filter 104 is output in which the in-band signal component is attenuated to about 5%.

In proximity and vicinity wireless communication such as in ISO 14443, not only is there a range in the degree of modulation in terms of the standard, there is also a broad range in the signal amplitudes of Vinp and Vinn due to the influence of the output capability of the reader/writer device, the distance from the reader/writer device, and the like. In other words, the signal amplitude of Vinp and Vinn may become extremely low, or may become extremely high. Thus, Vinp and Vinn are presumed to have amplitudes greater than or equal to the dynamic range of differential amplifier circuit 102. When Vinp and Vinn have amplitudes greater than or equal to the dynamic range of differential amplifier circuit 102, the waveforms of Voutp and Voutn warp, and/or Voutp and Voutn ripple more than expected.

Accordingly, semiconductor device 10 includes clamp circuit 103.

Clamp circuit 103 has a first P-channel MOS transistor having a gate connected to Vinp and a source and drain connected to Vinn, and a second P-channel MOS transistor having a gate connected to Vinn and a source and drain connected to Vinp.

Due to this structure, clamp circuit 103 sets the electric potential difference between Vinp and Vinn to be less than or equal to threshold Vt of the P-channel MOS transistors.

In a case in which this threshold Vt is set to, for example, 350 mV, when the output of DC level extraction low-pass filter 104 has attenuated to 5% of the in-band signal component, rippling in the output of DC level extraction low-pass filter 104 becomes less than or equal to 18 mV.

Thus, by setting the hysteresis of comparator 105 to a value in which malfunction of comparator 105 does not occur even if rippling occurs at 18 mV in the output of DC level extraction low-pass filter 104, erroneous demodulation of the ASK modulated signal can be inhibited by semiconductor device 10.

The allowable range of variation required in the hysteresis properties of comparator 105 is greater than or equal to the rippling in the output of DC level extraction low-pass filter 104, and less than or equal to the peak voltage of the differentiated envelope signal.

As described above, the hysteresis properties of comparator 105 are an essential factor in determining the ASK modulated signal demodulation properties.

Accordingly, comparator 105 has a function of adjusting the width of the hysteresis.

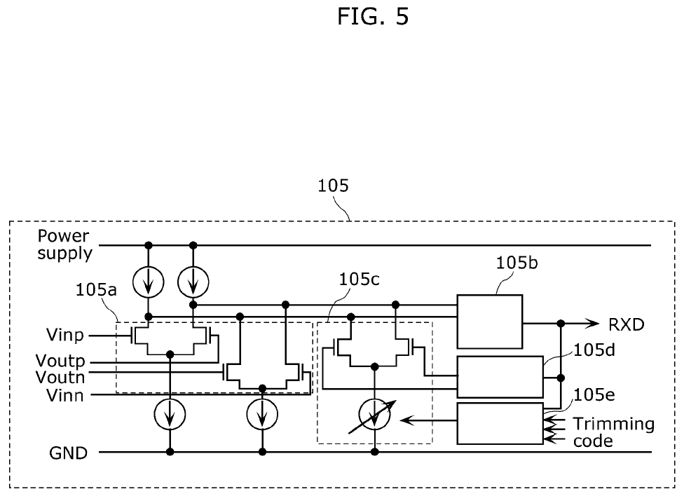

FIG. 5 is a circuit diagram illustrating the configuration of comparator 105.

As illustrated in FIG. 5, comparator 105 includes four-terminal differential input comparator 105a, current-voltage folded circuit 105b, hysteresis adjustment current source 105c, hysteresis width control logic 105d, and trimming control logic 105e.

Vinp, Vinn, Voutp, and Voutn are inputted into four-terminal differential input comparator 105a. That is to say, only the signals differentiated by high-pass filter 101b are inputted into four-terminal differential input comparator 105a.

Four-terminal differential input comparator 105a converts the voltage difference between the compared signals into current, and outputs the converted current to current-voltage folded circuit 105b.

Current-voltage folded circuit 105b once again converts the current outputted from four-terminal differential input comparator 105a into voltage to generate RXD, and outputs the generated RXD.

Hysteresis width control logic 105d feeds back, to hysteresis adjustment current source 105c, the signal for controlling the hysteresis width, based on the RXD outputted from current-voltage folded circuit 105b.

Trimming control logic 105e feeds back, to hysteresis adjustment current source 105c, the signal for trimming the hysteresis width, based on the RXD outputted from current-voltage folded circuit 105b and/or a signal inputted from an external source.

Hysteresis adjustment current source 105c adjusts the width of the hysteresis of comparator 105, based on the signal outputted from hysteresis width control logic 105d for controlling the switch and the signal outputted from trimming control logic 105e for controlling the current that flows to the current source.

Incidentally, the typical precision of applied voltage that can be generated from a detector for detecting a comparator is about 10 mV to 20 mV, thus not satisfying the applied voltage precision needed for detecting the hysteresis properties of comparator 105.

Thus, semiconductor device 10 includes trimming circuit 106 that generates differential voltage that is used for detecting the width of the hysteresis of comparator 105, from a bias circuit installed separately from the circuit that demodulates the ASK modulated signal.

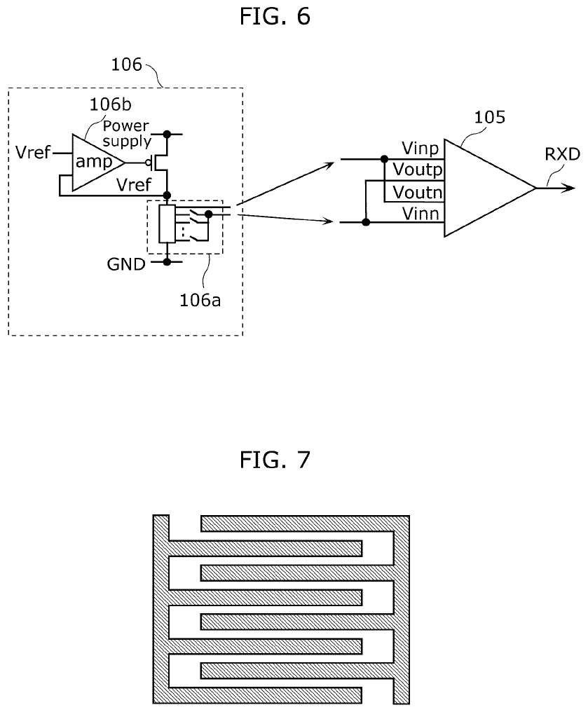

FIG. 6 is a block diagram illustrating the configuration of trimming circuit 106.

As illustrated in FIG. 6, trimming circuit 106 includes resistor ladder 106a and amp 106b.

Due to the above-described configuration, trimming circuit 106 is able to adjust the voltage to be outputted at a fine voltage difference on the order of several mV, based on the voltage of input voltage Vref.

Due to the above-described configuration, trimming circuit 106 is able to generate a precise voltage unaffected by the detecting environment such as temperature of semiconductor device 10, process variation during the manufacturing of semiconductor device 10, the precision of the applied voltage that the detector can generate, and the like.

Thus, highly precise adjustment of the hysteresis properties of comparator 105 is realized.

On the other hand, as described above, it is necessary to set the cutoff frequency of DC level extraction low-pass filter 104 to an extremely low frequency such as, e.g., 5.3 KHz. Thus, the layout areas of the resistor elements and the condenser elements constituting DC level extraction low-pass filter 104 are on a scale that cannot be ignored with respect to the layout area of semiconductor device 10.

Hereinafter, a layout method, proposed by the inventors, for DC level extraction low-pass filter 104 that makes it possible to achieve favorable layout area efficiency in DC level extraction low-pass filter 104 that includes resistors and capacitors will be described in detail.

First, the layout structure of first resistor 201a, second resistor 201b, first capacitor 202a, second capacitor 202b, and third capacitor 203 included in DC level extraction low-pass filter 104 will be described.

First capacitor 202a and second capacitor 202b are MOS capacitors. On the other hand, third capacitor 203 is a MOM capacitor.

As described above, a MOS capacitor is a capacitor realized by the gate capacitance of a transistor.

As described above, a MOM capacitor is a capacitor realized by the inter-wiring capacitance of wirings provided in the same wiring layer.

FIG. 7 is a schematic diagram illustrating the layout structure, in plan view, of a typical MOM capacitor.

As illustrated in FIG. 7, the MOM capacitor is typically, as disclosed in PTL 3, realized by the inter-wiring capacitance resulting from two wirings having interleaved comb-shaped structures.

First resistor 201a and second resistor 201b are resistors realized by polysilicon.

Hereinafter, the layout structure of the MOM capacitor that realizes third capacitor 203 (hereinafter, may also be referred to as “MOM capacitor according to Embodiment 1”), the MOS capacitor that realizes first capacitor 202a and second capacitor 202b (hereinafter, may also be referred to as “MOS capacitor according to Embodiment 1”), and the resistor that realizes first resistor 201a and second resistor 201b (hereinafter, may also be referred to as “resistor according to Embodiment 1”) will be described with reference to the Drawings.

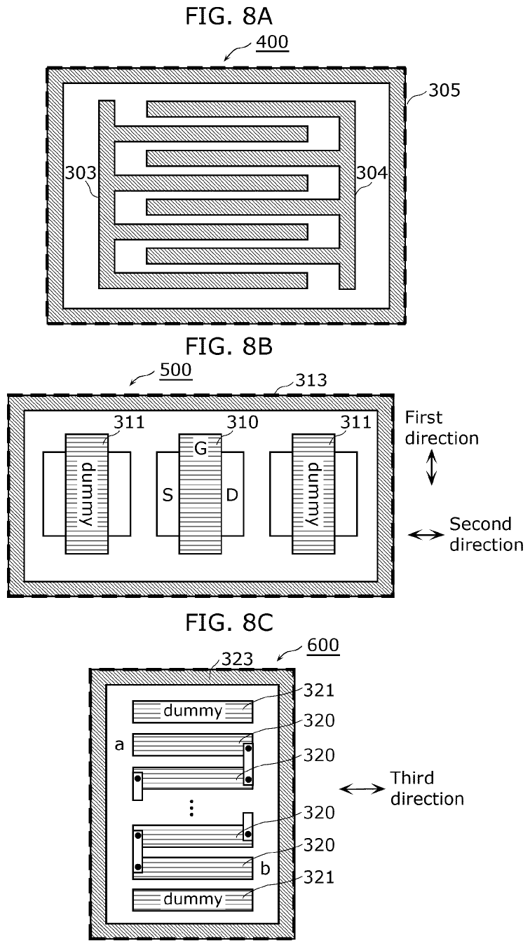

FIG. 8A is a schematic diagram illustrating the layout structure, in plan view, of MOM capacitor-provided region 400 in which the MOM capacitor according to Embodiment 1 is provided.

As illustrated in FIG. 8A, MOM capacitor-provided region 400 is a region in which first wiring 303 provided in a wiring layer, second wiring 304 provided in the same wiring layer, and guard ring 305 consisting of a wiring, surrounding first wiring 303 and second wiring 304, and provided in the same wiring layer are provided.

Here, the outer circumference of MOM capacitor-provided region 400 is the outer circumference of guard ring 305 illustrated by the dashed line in FIG. 8A.

The MOM capacitor according to Embodiment 1 is realized by the inter-wiring capacitance resulting from first wiring 303 and second wiring 304, which are adjacent to each other and each have a comb-shaped structure.

Guard ring 305 is connected to a predetermined electric potential such as ground electric potential. Accordingly, guard ring 305 inhibits the influence from the outside of guard ring 305 on the MOM capacitor according to Embodiment 1, and/or inhibits breakage of the MOM capacitor according to Embodiment 1 due to electrostatic discharge (ESD).

In Embodiment 1, MOM capacitor area Mmom that is the area of MOM capacitor-provided region 400 is defined as the area of the region surrounded by the outer circumference of guard ring 305.

However, when it is unnecessary to consider the influence from the outside on the MOM capacitor according to Embodiment 1, and/or it is unnecessary to consider breakage of the MOM capacitor according to Embodiment 1 due to ESD, providing guard ring 305 is not necessarily required. Thus, in such a case, MOM capacitor area Mmom of MOM capacitor-provided region 400 may be defined as the area of the region in which first wiring 303 and second wiring 304 are provided, not including the region in which guard ring 305 is provided.

FIG. 8B is a schematic diagram illustrating the layout structure, in plan view, of MOS capacitor-provided region 500 in which the MOS capacitor according to Embodiment 1 is provided.

As illustrated in FIG. 8B, MOS capacitor-provided region 500 is a region in which the following are provided: one or more MOS transistors 310 each having a different one of one or more gates that include polysilicon and extend parallel to each other (hereinafter, this extending direction may also be referred to as the “first direction”); one or more dummy MOS transistors 311 each having a gate that includes polysilicon and extends in the first direction; and guard ring 313 that includes polysilicon and surrounds the one or more MOS transistors 310 and the one or more dummy MOS transistors 311.

In Embodiment 1, the one or more MOS transistors 310 and the one or more dummy MOS transistors 311 are described as being N-channel MOS transistors. However, the one or more MOS transistors 310 and the one or more dummy MOS transistors 311 need not necessarily be limited to N-channel MOS transistors, and may be P-channel MOS transistors.

Here, the one or more MOS transistors 310 and the one or more dummy MOS transistors 311 are connected to ground electric potential.

Moreover, the one or more dummy MOS transistors 311 are disposed, in a second direction that is orthogonal to the first direction in plan view, at one or both of outermost positions of the region in which the one or more MOS transistors 310 and the one or more dummy MOS transistors 311 are disposed.

Here, the outer circumference of MOS capacitor-provided region 500 is the outer circumference of guard ring 313, illustrated by the dashed line in FIG. 8B.

The MOS capacitor according to Embodiment 1 is realized by connecting, to each other, the one or more gates in the respective one or more MOS transistors 310. Here, the source and drain of each of the one or more MOS transistors 310 are connected to ground electric potential.

Guard ring 313 is connected to electric potential such as ground electric potential. Accordingly, guard ring 313 inhibits the influence from the outside of guard ring 313 on the MOS capacitor according to Embodiment 1, and/or inhibits breakage of the MOS capacitor according to Embodiment 1 due to ESD.

In Embodiment 1, MOS capacitor area Mc that is the area of MOS capacitor-provided region 500 is defined as the area of the region surrounded by the outer circumference of guard ring 313.

However, when it is unnecessary to consider the influence from the outside on the MOS capacitor according to Embodiment 1, and/or it is unnecessary to consider breakage of the MOS capacitor according to Embodiment 1 due to ESD, providing guard ring 313 is not necessarily required. Thus, in such a case, MOS capacitor area Mc of MOS capacitor-provided region 500 may be defined as the area of the region in which the one or more MOS transistors 310 and the one or more dummy MOS transistors 311 are provided, not including the region in which guard ring 313 is provided.

Furthermore, in a case in which it is not necessary to consider the processing precision of the one or more MOS transistors 310, providing the one or more dummy MOS transistors 311 in MOS capacitor-provided region 500 is not necessarily required. In such a case, it is not necessary to provide the one or more dummy MOS transistors 311 in MOS capacitor-provided region 500.

FIG. 8C is a schematic diagram illustrating the layout structure, in plan view, of resistor-provided region 600 in which the MOS capacitor according to Embodiment 1 is provided.

As illustrated in FIG. 8C, resistor-provided region 600 is a region in which the following are provided: one or more polysilicon segments 320 extending parallel to each other (hereinafter, this extending direction may also be referred to as the “third direction”); one or more dummy polysilicon segments 321 extending in the third direction; and guard ring 323 that includes polysilicon and surrounds the one or more polysilicon segments 320 and the one or more dummy polysilicon segments 321.

The resistor according to Embodiment 1 is formed by connecting the one or more polysilicon segments 320 together. In the example illustrated in FIG. 8C, the resistor according to Embodiment 1 is formed by connecting the one or more polysilicon segments 320 from a to b in series. However, the resistor according to Embodiment 1 is not necessarily required to be limited to a structure in which the one or more polysilicon segments 320 are connected in series. The resistor according to Embodiment 1 may, for example, have a structure in which the one or more polysilicon segments 320 are connected in parallel, or may have a structure in which the one or more polysilicon segments 320 are connected in parallel and connected in series.

Guard ring 323 is connected to a predetermined electric potential such as ground electric potential. Accordingly, guard ring 323 inhibits the influence from the outside of guard ring 323 on the resistor according to Embodiment 1, and/or inhibits breakage of the resistor according to Embodiment 1 due to ESD.

In Embodiment 1, resistor area Mr that is the area of resistor-provided region 600 is defined as the area of the region surrounded by the outer circumference of guard ring 323.

However, when it is unnecessary to consider the influence from the outside on the resistor according to Embodiment 1, and/or it is unnecessary to consider breakage of the resistor according to Embodiment 1 due to ESD, providing guard ring 323 is not necessarily required. Thus, in such a case, resistor area Mr of resistor-provided region 600 may be defined as the area of the region in which the one or more polysilicon segments 320 and the one or more dummy polysilicon segments 321 are provided, not including the region in which guard ring 323 is provided.

Furthermore, in a case in which it is not necessary to consider the processing precision of the one or more polysilicon segments 320, providing the one or more dummy polysilicon segments 321 in resistor-provided region 600 is not necessarily required. In such a case, it is not necessary to provide the one or more dummy polysilicon segments 321 in resistor-provided region 600.

Next, the resistivity and the capacitance rate, which are necessary for describing the layout method for DC level extraction low-pass filter 104, will be described.

The basic principle of this layout method is that by stacking the MOM capacitor according to Embodiment 1 on the resistor according to Embodiment 1 and/or the MOS capacitor according to Embodiment 1, the layout area efficiency of DC level extraction low-pass filter 104 becomes favorable.

In DC level extraction low-pass filter 104, first resistor 201a and second resistor 201b correspond to the resistor according to Embodiment 1, first capacitor 202a and second capacitor 202b correspond to the MOS capacitor according to Embodiment 1, and third capacitor 203 corresponds to the MOM capacitor according to Embodiment 1.

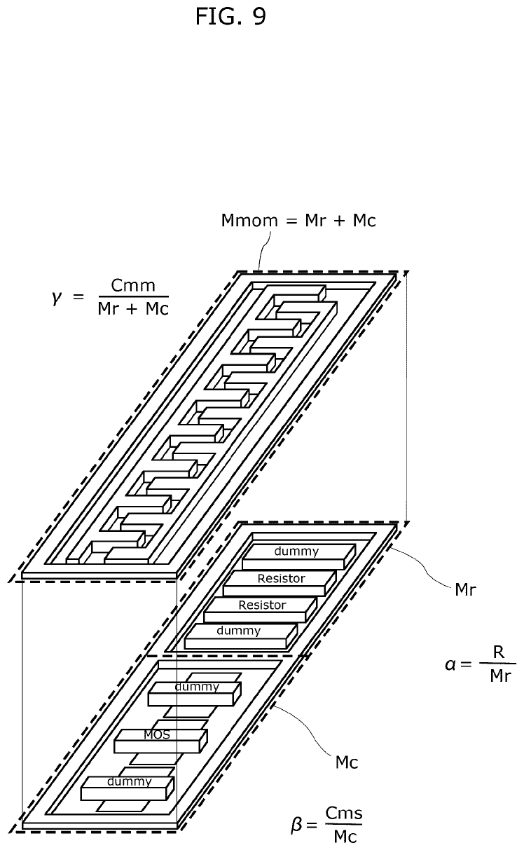

FIG. 9 is a schematic diagram illustrating the layout structure, when viewed obliquely from above, of the MOM capacitor according to Embodiment 1 stacked on the resistor according to Embodiment 1 and the MOS capacitor according to Embodiment 1.

The example illustrated in FIG. 9 is a layout structure example in which, in plan view, the shape of the region in which resistor-provided region 600 and MOS capacitor-provided region 500 are joined together matches the shape of MOM capacitor-provided region 400. Thus, in this layout structure, MOM capacitor area Mmom of MOM capacitor-provided region 400 is equal to the sum of resistor area Mr of resistor-provided region 600 and MOS capacitor area Mc of MOS capacitor-provided region 500.

Hereinafter, a layout structure in which the layout area efficiency of DC level extraction low-pass filter 104 is favorable is described by way of a layout structure in which, as exemplified in FIG. 9, in plan view, the shape of the region in which resistor-provided region 600 and MOS capacitor-provided region 500 are joined together matches the shape of MOM capacitor-provided region 400. However, as long as the layout structure in which the layout area efficiency of DC level extraction low-pass filter 104 is favorable is a layout structure in which the MOM capacitor according to Embodiment 1 is stacked on the resistor according to Embodiment 1 and/or the MOS capacitor according to Embodiment 1, the layout structure is not necessarily required to be limited to a layout structure in which, in plan view, the shape of the region in which resistor-provided region 600 and MOS capacitor-provided region 500 are joined together matches the shape of MOM capacitor-provided region 400.

Furthermore, the layout structure exemplified in FIG. 9 is an example in which the wiring that forms the MOM capacitor is provided in one wiring layer, but the wiring that forms the MOM capacitor is not necessarily required to be limited to a configuration of being provided in one wiring layer. The wiring that forms the MOM capacitor may be, for example, provided across two or more wiring layers.

As illustrated in FIG. 9, when Mr denotes the resistor area in resistor-provided region 600 and R denotes the resistance value of the resistor provided in resistor-provided region 600, resistivity a is defined as R/Mr.

Furthermore, when Mc denotes the MOS capacitor area in MOS capacitor-provided region 500 and Cms denotes the capacitance value of the MOS capacitor provided in MOS capacitor-provided region 500, MOS capacitance rate β is defined as Cms/Mc.

Furthermore, when Mmom denotes the MOM capacitor area in MOM capacitor-provided region 400 and Cmm denotes the capacitance value of the MOM capacitor provided in MOM capacitor-provided region 400, MOM capacitance rate γ is defined as Cmm/Mmom.

Note that here, it goes without saying that Mmom may be replaced with Mr+Mc.

Next, a specific method for making the layout area efficiency of DC level extraction low-pass filter 104 favorable will be described. Using resistivity a, MOS capacitance rate β, and MOM capacitance rate γ as defined above, resistance value R is represented by R=α×Mr, capacitance value Cms is represented by Cms=β×Mc, and capacitance value Cmm is represented by Cmm=γ×(Mr+Mc).

Typically, cutoff frequency ft of a primary filter is represented by the following equation.

$$ft = \frac{1}{2 π RC} \qquad [ Math . 4 ]$$

Thus, using the above-described resistance value R, capacitance value Cms, and capacitance value Cmm, ft is represented as the following equation.

$$ft = \frac{1}{2 πα Mr \{ β Mc + γ ( Mr + Mc ) \}} \qquad [ Math . 5 ]$$

When expanded, this equation is as follows.

$$ft = \frac{1}{2 π \{ αβ Mr Mc + αγ {Mr}^{2} + αγ MrMc ) \}} \qquad [ Math . 6 ]$$

Here, taking Mr+Mc as total area S, since Mc is represented by Mc=S−Mr, ft is represented as the following equation.

$$ft = \frac{1}{2 π \{ αβ Mr ( S - Mr ) + αγ {Mr}^{2} + αγ Mr ( S - Mr ) \}} \qquad [ Math . 7 ]$$

When expanded and simplified, this equation is as follows.

$$\begin{matrix}( 1 ) & \\ ft = \frac{1}{2 π \{ αβ SMr - αβ {Mr}^{2} + αγ SMr ) \}} & [ Math . 8 ]\end{matrix}$$

In Equation (1), the following expression is the product of the resistance value and the capacitance value.

$$( αβ SMr - αβ {Mr}^{2} + αγ SMr ) \qquad [ Math . 9 ]$$

Therefore, this is a fixed value when the cutoff frequency is fixed. Thus, when this fixed value is taken to be x, x is as follows.

$$\begin{matrix}[ Math . 10 ] & \\ x = \{ αβ SMr - αβ {Mr}^{2} + αγ SMr \} & ( 2 )\end{matrix}$$

Expanding Equation (2), total area S is as follows.

$$\begin{matrix}[ Math . 11 ] & \\ S = \frac{( x + αβ Mr 2 )}{( αγ + αβ ) Mr} & ( 3 )\end{matrix}$$

$$S = \frac{x}{α Mr ( γ + β )} + \frac{β Mr}{( γ + β )}$$

As described above, x represented by Equation (2) is the product of the resistance value and the capacitance value, that is to say, RC.

$$ft = \frac{1}{2 π RC} \qquad [ Math . 12 ]$$

Thus, considering the relationship in the above equation, the following equation is derived.

$$x = RC = \frac{1}{2 πft} \qquad [ Math . 13 ]$$

Accordingly, the first item of Equation (3) is the following expression.

$$\frac{x}{α Mr ( γ + β )} \qquad [ Math . 14 ]$$

This expression can be represented as follows.

$$\begin{matrix}[ Math . 15 ] & \\ \frac{1}{2 π ft α Mr ( γ + β )} & ( 4 )\end{matrix}$$

Here, the following expression is taken to be the second item of Equation (3).

$$\begin{matrix}[ Math . 16 ] & \\ \frac{β Mr}{( γ + β )} & ( 5 )\end{matrix}$$

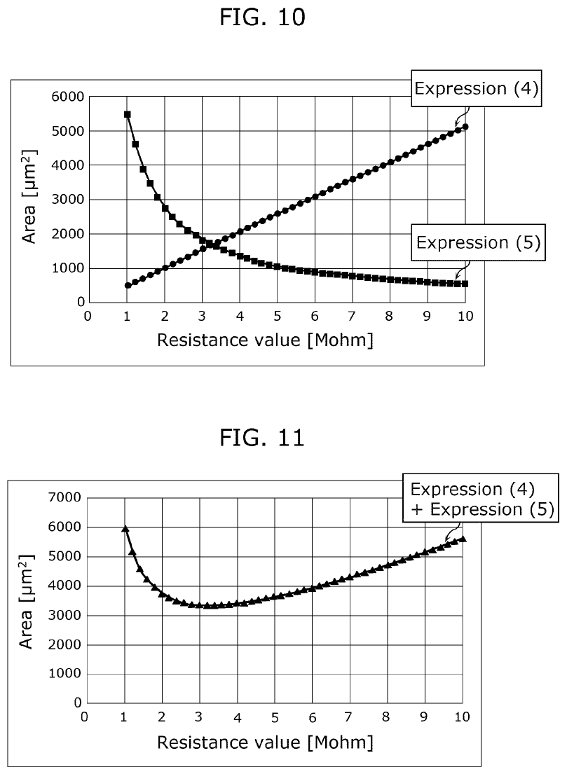

FIG. 10 is a graph illustrating the relationship between resistance value and area in Expression (4) and Expression (5).

FIG. 11 is a graph illustrating the relationship between resistance value and area in the sum of Expression (4) and Expression (5), that is to say, in Equation (3).

As is clear from FIG. 10 and FIG. 11, similar to total area S in Equation (3), that is to say, similar to the sum of resistor area Mr in resistor-provided region 600 and MOS capacitor area Mc in MOS capacitor-provided region 500, it is revealed that the resistance value at which total area S, which is also MOM capacitor area Mmom in MOM capacitor-provided region 400, is the smallest is the point at which the graph of Expression (4) and the graph of Expression (5) intersect in FIG. 10.

From this, the following relational expression is obtained.

$$\begin{matrix}[ Math . 17 ] & \\ \frac{x}{α Mr ( γ + β )} = \frac{β Mr}{( γ + β )} & ( 6 )\end{matrix}$$

Modifying Equation (6) and then rewriting the left side in terms of Mr gives the following equation.

$${Mr}^{2} = \frac{x}{αβ} = \frac{1}{( 2 π f αβ )} \qquad [ Math . 18 ]$$

From this, the following equation is obtained.

$$\begin{matrix}[ Math . 19 ] & \\ Mr = \sqrt{\frac{1}{2 π f αβ}} & ( 7 )\end{matrix}$$

As described above, the point at which total area S is the smallest is where Expression (4) and Expression (5) are equal, that is to say, in Equation (3), where Expression (4), which is the first item, and Expression (5), which is the second item, are equal.

At this time, when total area S in Equation (3) is taken to be two times Expression (5), which is the second item, and Mr is expressed using Equation (7), optimal total area Sbest at which total area S is the smallest, that is to say, the optimal total area S, is as follows.

$$Sbest = \frac{β}{γ + β} \times \sqrt{\frac{1}{2 π f αβ}} \times 2 \qquad [ Math . 20 ]$$

Here, a relational expression is considered with regard to the area of the capacitor.

As described above, cutoff frequency ft of a primary filter is represented by the following equation.

$$ft = \frac{1}{2 π RC} \qquad [ Math . 21 ]$$

Thus, the following equation is obtained.

$$C = \frac{1}{2 π fR} \qquad [ Math . 22 ]$$

Since resistance value R is R=α×Mr, from Equation (7), resistance value R is as follows.

$$R = α \times \sqrt{\frac{1}{2 π f αβ}} \qquad [ Math . 23 ]$$

Capacitance value C=Cmm+Cms becomes the following equation.

$$C = \frac{1}{2 π f α \sqrt{\frac{1}{2 π f αβ}}} \qquad [ Math . 24 ]$$

Expanding this equation, capacitance value C is as follows.

$$C = \frac{1}{\frac{\sqrt{2 π f α} \sqrt{2 π f α}}{\sqrt{2 π f α β}}} \qquad [ Math . 25 ]$$

$$C = \sqrt{\frac{β}{2 π f α}}$$

Here, when Cmm1 denotes the capacitance value of the MOM capacitor provided on resistor-provided region 600, Cmm1 can be determined by multiplying resistor area Mr in resistor-provided region 600 by MOM capacitance rate γ; thus, Cmm1 is as follows.

$$Cmm 1 = γ \sqrt{\frac{1}{2 π f α β}} \qquad [ Math . 26 ]$$

$$Cmm 1 = \sqrt{\frac{{γ}^{2}}{2 π f α β}}$$

MOS capacitor area Mc in MOS capacitor-provided region 500 can be determined by dividing the capacitance resulting from subtracting capacitance value Cmm1 from capacitance value C, by the total capacitance rate expressed by β+γ; thus, Mc is as follows.

$$Mc = \frac{1}{β + γ} ( \sqrt{\frac{β}{2 π f α}} - \sqrt{\frac{{γ}^{2}}{2 π f α β}} ) \qquad [ Math . 27 ]$$

$$Mc = \frac{1}{β + γ} ( \sqrt{\frac{{β}^{2}}{2 π f α β}} - \sqrt{\frac{{γ}^{2}}{2 π f α β}} )$$

$$Mc = \frac{1}{β + γ} ( \frac{β}{\sqrt{2 π f α β}} - \frac{γ}{\sqrt{2 π f α β}} )$$

$$Mc = \frac{1}{β + γ} ( \frac{β - γ}{\sqrt{2 π f α β}} )$$

$$Mc = \frac{β - γ}{β + γ} \times \sqrt{\frac{1}{2 π f α β}}$$

Here, as indicated in Equation (7), Mr is the following expression.

$$\sqrt{\frac{1}{2 π f α β}} \qquad [ Math . 28 ]$$

Thus, the following equation is obtained.

$$[ Math . 29 ]$$

$$Mc = \frac{β - γ}{β + γ} \times Mr \qquad ( 8 )$$

Thus, setting MOS capacitor area Mc in MOS capacitor-provided region 500 to (β−γ)/(β+γ) times resistor area Mr in resistor-provided region 600 makes it possible to maximize the layout area efficiency of DC level extraction low-pass filter 104 that realizes the desired cutoff frequency.

However, in a semiconductor manufacturing process, when forming each element, variation occurring in the properties of each element cannot be avoided. Thus, in order to make the layout area efficiency of DC level extraction low-pass filter 104 that realizes the desired cutoff frequency favorable, MOS capacitor area Mc in MOS capacitor-provided region 500 may be set to at least (β−γ)/(β+γ) times resistor area Mr in resistor-provided region 600, so that the desired cutoff frequency can be realized even if variation occurs in the properties of the elements.

In this case, Mc and Mr satisfy the following inequalities, respectively.

$$Mc ≧ \frac{β - γ}{β + γ} \times Mr \qquad [ Math . 30 ]$$

$$Mr ≦ \sqrt{\frac{1}{2 π f α β}}$$

It is known that typically, in a semiconductor manufacturing process, the resistance value and the capacitance value vary by about ±30% due to variation in processing dimensions, variation in oxidation states, and the like.

For example, in a case in which the resistance value and the capacitance value have variation of about ±30%, MOS capacitor area Mc in MOS capacitor-provided region 500 may be set to at least (β−γ)/(β+γ) times and at most six times resistor area Mr in resistor-provided region 600.

### Embodiment 2

Embodiment 2 describes a layout method for laying out DC level extraction low-pass filter 104, in a usage case of newly designing semiconductor device 10 including a design margin during initial design in a new semiconductor manufacturing process.

First, the optimal resistor area of resistor-provided region 600 when the cutoff frequency of DC level extraction low-pass filter 104 has been uniquely determined will be described.

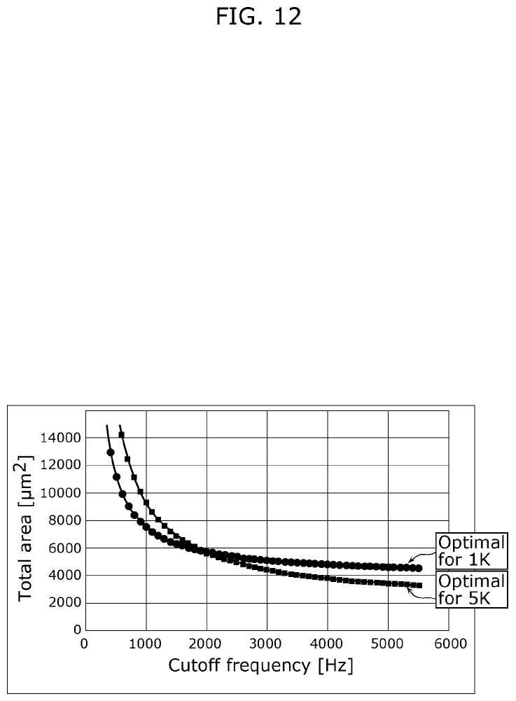

FIG. 12 is a graph illustrating the relationship between the cutoff frequency and the total area when the resistor area has been fixed at the optimal area for a cutoff frequency of 5 KHz and the total area S has been changed, and a graph illustrating the relationship between the cutoff frequency and the total area when the resistor area has been fixed at the optimal area for a cutoff frequency of 1 KHz and the total area S has been changed.

As revealed from FIG. 12, these graphs intersect each other where the cutoff frequency is just over 2 KHz.

In other words, the total areas of each of these two graphs are equal where the cutoff frequency is just over 2 KHz.

As described above, total area S is represented by Equation (3).

When, within a range of manufacturing variation in manufacturing semiconductor device 10, f1 denotes a minimum cutoff frequency that is a minimum cutoff frequency of DC level extraction low-pass filter 104 and f2 denotes a maximum cutoff frequency that is a maximum cutoff frequency of DC level extraction low-pass filter 104, and assuming that the manufacturing variation does not occur, f3 denotes a cutoff frequency at a point of intersection between: (1) a waveform of a cutoff frequency of DC level extraction low-pass filter 104 when the MOS capacitor area is changed while the resistor area that is most suitable for DC level extraction low-pass filter 104 to realize the minimum cutoff frequency is fixed; and (2) a waveform of a cutoff frequency of DC level extraction low-pass filter 104 when the MOS capacitor area is changed while the resistor area that is most suitable for DC level extraction low-pass filter 104 to realize the maximum cutoff frequency is fixed.

In the two graphs illustrated in FIG. 12, 5 KHz corresponds to f1, 1 KHz corresponds to f2, and just over 2 KHz corresponds to f3.

When x in Equation (2) is x3 in a case in which the cutoff frequency is f3, x3 is as follows.

$$[ Math . 31 ]$$

$$\times 3 = \frac{1}{2 π f 3} \qquad ( 9 )$$

Furthermore, when M1 denotes the resistor area that is optimal at minimum cutoff frequency f1 and M2 denotes the resistor area that is optimal at maximum cutoff frequency f2, the point at which the two graphs illustrated in FIG. 12 intersect is, from Equation (3), represented by the following relational expression.

$$\frac{\times 3}{α M 1 ( γ + β )} + \frac{β M 1}{( γ + β )} = \frac{\times 3}{α M 2 ( γ + β )} + \frac{β M 2}{( γ + β )} \qquad [ Math . 32 ]$$

Simplifying by canceling out (γ+β) from both sides of this equation gives the following equation.

$$\frac{\times 3}{α M 1} + α β M 1 = \frac{\times 3}{α M 2} + α β M 2 \qquad [ Math . 33 ]$$

Rewriting this equation in terms of x3 gives x3=αβM1M2. When resistor area M1 and resistor area M2 in this equation are represented by the expression of Equation (7) and x3 is represented by Equation (9), the following equation results.

$$[ Math . 34 ]$$

$$\frac{1}{2 π f 3} = α β \times \sqrt{\frac{1}{2 π f 1 α β}} \times \sqrt{\frac{1}{2 π f 2 α β}} \qquad ( 10 )$$

Rewriting this equation to an equation that solves for f3 gives the following.

$$f 3 = \sqrt{f 1 f 2} \qquad [ Math . 35 ]$$

Furthermore, rewriting this equation to an equation that solves for f2 gives the following.

$$f 2 = \frac{f {3}^{2}}{f 1} \qquad [ Math . 36 ]$$

Here, it is assumed that in the semiconductor manufacturing process, the resistance value and the capacitance value fluctuate by about ±30% due to variation in processing dimensions, variation in oxidation states, and the like.

Even if the resistance value and the capacitance value vary in semiconductor device 10, the cutoff frequency of DC level extraction low-pass filter 104 shifting to the low-frequency side is not a problem in terms of practical usage.

As described above, cutoff frequency ft is as represented by the following equation.

$$f t = \frac{1}{2 π R C} \qquad [ Math . 37 ]$$

Thus, when R and C both fluctuate by −30%, the cutoff frequency shifts to the high-frequency side. Anticipating this shift toward the high-frequency side, R and C may be increased in the design of DC level extraction low-pass filter 104.

In other words, since 1/(0.7×0.7)=2, it is sufficient to shift the cutoff frequency serving as the design target to the low-frequency side in advance, in order to cause the cutoff frequency to always be less than or equal to a predetermined frequency, even in a case in which the resistance value and the capacitance value vary and the cutoff frequency shifts to the high-frequency side.

In other words, when the predetermined frequency is 5 KHz, it is sufficient to set the cutoff frequency serving as the design target to ½ of 5 KHz, that is, 2.5 KHz.

The design approach regarding the cutoff frequency serving as the design target is a design approach for when there is fluctuation of about ±30% in the resistance value and the capacitance value. In contrast, in the initial design in a new semiconductor manufacturing process, since the actual amount by which the resistance value and the capacitance value are able to vary in this process is unknown, it is necessary to start the design assuming an amount of fluctuation (for example, ±50%) that is larger than the actual amount by which the resistance value and the capacitance value are able to fluctuate (for example, ±30%). Thus, when it has been determined, after semiconductor device 10 has become a product, that the amount of fluctuation predicted during design is greater than the actual ability to fluctuate, an excessive layout area that is normally unneeded becomes included in the layout area of semiconductor device 10 as a result.

On the other hand, in, for example, a wireless communication device such as a contactless IC card, there is a requirement to store as much power as possible in inter-power supply capacitance in preparation for the supply of instantaneous power during communication.

This instantaneous power during communication includes, for example, instantaneous power for writing data to non-volatile memory, instantaneous power for generating high voltage by a charge pump circuit, and instantaneous power for performing computation that involves high speed and a large amount of processing, as in encryption processing and the like.

That is to say, increasing the inter-power supply capacitance in a wireless communication device leads to enhanced performance of the wireless communication device, such as higher speed in computation processing and an increase in the number of bits to be simultaneously written to nonvolatile memory.

Thus, Embodiment 2 proposes determining the layout structure of DC level extraction low-pass filter 104 with the design approach described below.

As described above, in a wireless communication device such as a contactless IC card, increasing the inter-power supply capacitance leads to enhanced performance of the wireless communication device. Thus, as a result, in semiconductor device 10 included in wireless communication device 100, when some of the capacitance provided in MOS capacitor-provided region 500 is excess MOS capacitance that is not normally needed, this excess MOS capacitance may be repurposed for inter-power supply capacitance in semiconductor device 10.

Thus, as the layout configuration of DC level extraction low-pass filter 104, a structure that makes it possible to relatively easily repurpose the excess MOS capacitance for inter-power supply capacitance may be adopted.

In other words, for example, when, as f1, f2, and f3 that satisfy Equation (10), setting f1 to 5 KHz, f2 to 1.25 KHz, and f3 to 2.5 KHz, DC level extraction low-pass filter 104 may be designed with the cutoff frequency serving as the design target being set to 1.25 KHz, and the layout of DC level extraction low-pass filter 104 may be configured such that after the designing, some of the MOS capacitance included in MOS capacitor-provided region 500 can be repurposed for inter-power supply capacitance by changing the layout of only the wiring layer, within a range of the actual cutoff frequency being 2.5 KHz or higher.

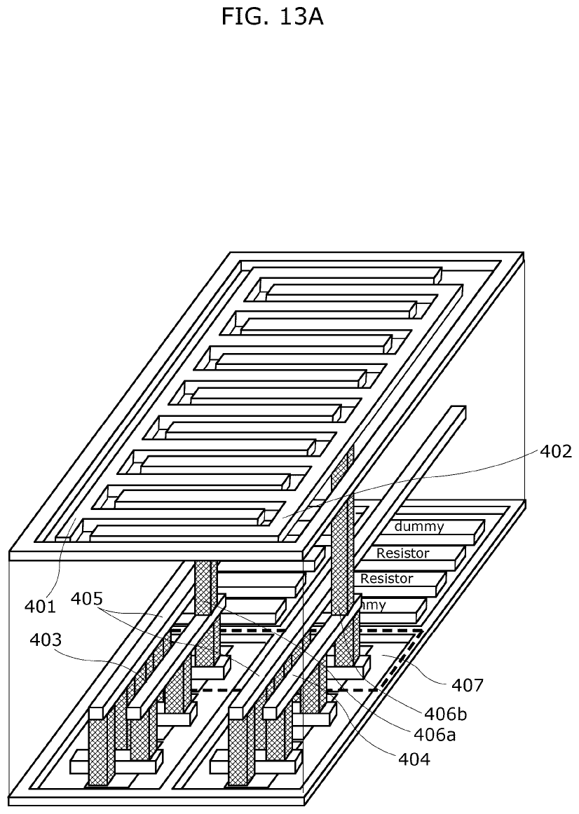

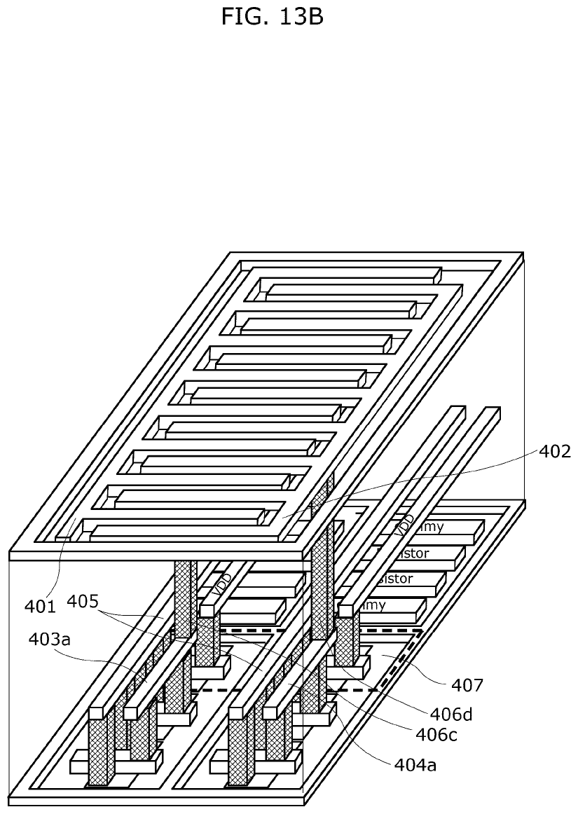

FIG. 13A is a schematic diagram illustrating the layout structure, when viewed obliquely from above, of DC level extraction low-pass filter 104 before changing the layout of the wiring layer. FIG. 13B is a schematic diagram illustrating the layout structure, when viewed obliquely from above, of DC level extraction low-pass filter 104 after changing the layout of the wiring layer.

Wiring 401 is wiring connected to a node that is connected to Voutp (hereinafter, may also be referred to as the “Voutp node”), and is one wiring of two wirings that form third capacitor 203, which is a MOM capacitor.

Wiring 402 is wiring connected to a node connected to Voutn (hereinafter, may also be referred to as the “Voutn node”), and is the other wiring of the two wirings that form third capacitor 203, which is a MOM capacitor.

Wiring 403 is wiring connected to the Voutp node, and is wiring that is connected to wiring 401 through via 406a and connected to the gate of one or more MOS transistors 310 that form first capacitor 202a, which is a MOS capacitor.

Wiring 403a is wiring connected to the Voutp node, and is wiring that is connected to wiring 401 through via 406c and connected to the gate of one or more MOS transistors 310 that form first capacitor 202a, which is a MOS capacitor.

Wiring 404 is wiring connected to the Voutn node, and is wiring that is connected to wiring 402 through via 406b and connected to the gate of one or more MOS transistors 310 that form second capacitor 202b, which is a MOS capacitor.

Wiring 404a is wiring connected to the Voutn node, and is wiring that is connected to wiring 402 through via 406d and connected to the gate of one or more MOS transistors 310 that form second capacitor 202b, which is a MOS capacitor.

Wiring 405 is wiring connected to ground, and is wiring that is connected to the source and drain of one or more MOS transistors 310 that form first capacitor 202a, and to the source and drain of one or more MOS transistors 310 that form second capacitor 202b.

Hereinafter, a case in which the target range of the cutoff frequency, in the range of manufacturing variation, of DC level extraction low-pass filter 104 is set to 1.25 K and higher is described as an example.

In this case, f1 is 5.0 KHz, f2 is 1.25 KHz, and f3 is 2.5 KHz. Furthermore, here, resistivity a is set to 1.37 Kohm, MOS capacitance rate β is set to 4.1 f, and MOM capacitance rate γ is set to 1.72 f.

In this case, when the cutoff frequency of DC level extraction low-pass filter 104 is 5.0 KHz, by Equation (3), the resistance value at which total area S is lowest is 3.2 Mohm, and the MOS capacitance at that time is 5.7 pF.

In contrast, when the cutoff frequency of DC level extraction low-pass filter 104 is 1.25 KHz, by Equation (3), the resistance value at which total area S is lowest is 6.6 Mohm, and the MOS capacitance at that time is 11.3 pF.

In this case, design is begun by setting the resistance value of the resistor to 3.2 Mohm in consideration of a case in which the cutoff frequency is 5.0 KHz, and setting the capacitance value of the MOS capacitor to 11.3 pF in consideration of a case in which the cutoff frequency is 1.25 KHz. Thus, as a result, when the cutoff frequency is set to 5.0 KHz, MOS capacitance of 5.6 pF is excess MOS capacitance.

Here, assuming that region 407 surrounded by the dashed line in FIG. 13A and FIG. 13B is the region in which 5.6 pF of capacitance, which is the excess MOS capacitance, is provided, changing the connection of the gate of one or more MOS transistors 310 included in region 407 from the connection state illustrated in FIG. 13A to the connection state illustrated in FIG. 13B makes it possible to repurpose this excess MOS capacitance for inter-power supply capacitance.

Thus repurposing the excess MOS capacitance for inter-power supply capacitance makes it possible to effectively utilize region 407 as a region for enhancing the performance of wireless communication device 100. That is to say, the layout area of semiconductor device 10 can be efficiently utilized.

Furthermore, as illustrated in FIG. 13A and FIG. 13B, repurposing of the excess MOS capacitance for inter-power supply capacitance can be realized by changing only: the wirings provided in the wiring layer on the lower layer side in the Drawings; and the vias that connect the wirings in the wiring layer on the lower layer side in the Drawings to the wirings in the wiring layer on the upper layer side in the Drawings.

Thus, cost related to changing the layout in repurposing the excess MOS capacitance for the inter-power supply capacitance can be reduced.

### (Supplement)

The semiconductor device according to the one aspect of the present disclosure has been described based on Embodiments 1 and 2, but the present disclosure is not intended to be limited to these Embodiments. One or a plurality of aspects of the present disclosure may thus include forms obtained by making various modifications to the above embodiments that can be conceived by those skilled in the art, as well as forms obtained by combining constituent elements in different embodiments, without materially departing from the spirit of the present disclosure.

### INDUSTRIAL APPLICABILITY

The present disclosure can be widely used in semiconductor devices and the like.

1. A semiconductor device comprising:
a filter circuit including:
a resistor;
a metal oxide semiconductor (MOS) capacitor; and
a metal oxide metal (MOM) capacitor stacked on at least one of the resistor or the MOS capacitor, wherein
the following inequalities are satisfied:
$$Mc \geq \frac{β - γ}{β + γ} \times Mr \qquad [ Math . 1 ]$$
$$Mr \leq \sqrt{\frac{1}{2 π f t α β}}$$
where
ft denotes a cutoff frequency of the filter circuit,
Mr denotes a resistor area that is an area, in a plan view, of a resistor-provided region in which the resistor is provided,
Mc denotes a MOS capacitor area that is an area, in the plan view, of a MOS capacitor-provided region in which the MOS capacitor is provided,
α denotes a resistivity obtained by dividing a resistance value of the resistor by the resistor area,
β denotes a MOS capacitance rate obtained by dividing a capacitance value of the MOS capacitor by the MOS capacitor area, and
γ denotes a MOM capacitance rate obtained by dividing a capacitance value of the MOM capacitor by a MOM capacitor area that is an area, in the plan view, of a MOM capacitor-provided region in which the MOM capacitor is provided.

2. The semiconductor device according to claim 1, wherein
the resistor is realized by connecting one or more resistors to each other, the one or more resistors each consisting of a different one of one or more polysilicon segments that extend parallel to each other, and
in the plan view, an outer circumference of the resistor-provided region is an outer circumference of a guard ring that includes polysilicon, the guard ring surrounding the one or more polysilicon segments.

3. The semiconductor device according to claim 2, wherein
in the plan view, the guard ring further surrounds one or more dummy polysilicon segments that extend in a direction parallel to a direction in which the one or more polysilicon segments extend.

4. The semiconductor device according to claim 1, wherein
the MOS capacitor is realized by connecting, to each other, one or more gates that include polysilicon and are each in a different one of one or more MOS transistors, the one or more gates extending parallel to each other, and
in the plan view, an outer circumference of the MOS capacitor-provided region is an outer circumference of a guard ring that includes polysilicon, the guard ring surrounding the one or more MOS transistors.

5. The semiconductor device according to claim 4, wherein
in the plan view, the guard ring further surrounds one or more dummy MOS transistors each including a gate that includes polysilicon and extends in a direction parallel to a direction in which the one or more gates extend.

6. The semiconductor device according to claim 1, wherein
the MOM capacitor is realized by inter-wiring capacitance between a first wiring and a second wiring that are provided in a wiring layer, and
in the plan view, an outer circumference of the MOM capacitor-provided region is an outer circumference of a guard ring consisting of a wiring, the guard ring surrounding the first wiring and the second wiring.

7. A semiconductor device comprising:
a filter circuit including:
a first signal input node into which one signal of differential signals is inputted;
a second signal input node into which an other signal of the differential signals is inputted;
a first signal output node;
a second signal output node;
a first resistor including one end connected to the first signal input node and an other end connected to the first signal output node;
a second resistor including one end connected to the second signal input node and an other end connected to the second signal output node;
a first capacitor including one end connected to the first signal output node and an other end connected to ground;
a second capacitor including one end connected to the second signal output node and an other end connected to the ground; and
a third capacitor including one end connected to the first signal output node and an other end connected to the second signal output node, wherein
the first capacitor is realized by one or more MOS transistors each including a gate that is connected to the first signal output node and a source and a drain that are each connected to the ground,
the second capacitor is realized by one or more MOS transistors each including a gate that is connected to the second signal output node and a source and a drain that are each connected to the ground,
the third capacitor is realized by inter-wiring capacitance between a first wiring and a second wiring, the first wiring being connected to the first signal output node, the second wiring being connected to the second signal output node, and
the third capacitor is provided by being stacked on at least one of the first resistor, the second resistor, the first capacitor, or the second capacitor.

8. The semiconductor device according to claim 7, further comprising:
upstream of the filter circuit,
a high-pass filter; and
an amplifier circuit; and
downstream of the filter circuit,
a comparator having hysteresis.

9. The semiconductor device according to claim 8, wherein
the comparator includes a function of adjusting a width of the hysteresis.

10. The semiconductor device according to claim 9, further comprising:
a trimming circuit that adjusts the width of the hysteresis of the comparator.

11. The semiconductor device according to claim 8, further comprising:
a clamp circuit that includes a P-channel MOS transistor and that clamps an output of the amplifier circuit.

12. The semiconductor device according to claim 7, wherein
the following inequality is satisfied:
$$f 3 = \sqrt{f 1 \times f 2} \qquad [ Math . 2 ]$$
where
within a range of manufacturing variation in manufacturing the semiconductor device, f1 denotes a minimum cutoff frequency that is a lowest cutoff frequency of the filter circuit and f2 denotes a maximum cutoff frequency that is a highest cutoff frequency of the filter circuit, and
when assuming that the manufacturing variation does not occur,
f3 denotes a cutoff frequency at a point of intersection between:
(1) a waveform of a cutoff frequency of the filter circuit when an area of a first capacitor-provided region is changed while an area of a first resistor-provided region that is most suitable for the filter circuit to realize the minimum cutoff frequency is fixed, the first capacitor-provided region being a region in which the first capacitor and the second capacitor are provided, the first resistor-provided region being a region in which the first resistor and the second resistor are provided; and
(2) a waveform of a cutoff frequency of the filter circuit when an area of a second capacitor-provided region is changed while an area of a second resistor-provided region that is most suitable for the filter circuit to realize the maximum cutoff frequency is fixed, the second capacitor-provided region being a region in which the first capacitor and the second capacitor are provided, the second resistor-provided region being a region in which the first resistor and the second resistor are provided.
